(19) United States
(12) Patent Application Publication
(10) Pub. No.: US 2025/0256607 A1
(43) Pub. Date: Aug. 14, 2025

(54) Insulation Error Detection Based on AC Voltage Components of An Activation Signal in The DC Voltage Side of an AC Voltage Charging Circuit

(71) Applicant: Schaeffler Technologies AG & Co. KG, Herzogenaurach (DE)

(72) Inventors: Franz Pfeilschifter, Walderbach (DE); Martin Götzenberger, Ingolstadt (DE)

(73) Assignee: Schaeffler Technologies AG & Co. KG, Herzogenaurach (DE)

(21) Appl. No.: 19/077,576

(22) Filed: Mar. 12, 2025

Related U.S. Application Data
(63) Continuation of application No. PCT/EP2023/073192, filed on Aug. 24, 2023.

(30) Foreign Application Priority Data
Sep. 12, 2022 (DE) 10 2022 209 506.5

(51) Int. Cl. B60L 53/62; G01R 31/52

(52) U.S. Cl. CPC B60L 53/62; G01R 31/52; B60L 2210/10; B60L 2210/30

(57) ABSTRACT

A method for detecting an isolation fault in a vehicle charging circuit is provided. The circuit has a DC voltage side which is isolated from a protective conductor potential, an AC voltage side and a controlled rectifier via which the DC voltage side is connected to the AC voltage side. The controlled rectifier is operated in a clocked mode according to an actuation signal. The following steps are also provided: measurement of a voltage present between DC voltage potentials of the DC voltage side or between a DC voltage potential of the DC voltage side and the protective conductor potential, and outputting of an isolation fault signal when the voltage contains an AC voltage component which partially or fully corresponds to the actuation signal and which has a signal strength above a predetermined threshold value.

### CROSS-REFERENCE TO RELATED APPLICATIONS

This application claims the benefit of International Application PCT/EP2023/073192, filed Aug. 24, 2023, which claims priority to German Application DE 10 2022 209 506.5, filed Sep. 12, 2022. The disclosures of the above applications are incorporated herein by reference.

### TECHNICAL FIELD

The disclosure relates to a method and a circuit for insulation error detection based on AC voltage Components of an activation signal in the dc voltage side of an ac voltage charging circuit.

### BACKGROUND

Vehicles with electric traction drive have a traction storage battery which provides electrical energy for the drive. To charge the battery, use is made of charging circuits having a rectifying unit by way of which, starting from an external AC voltage source, DC voltage can be provided for charging the accumulator. The rectifying unit is usually a controlled rectifier which may also be designed as an (active) power factor correction filter.

Due to the high traction power and the high charging power, the nominal voltage of the vehicle drive and traction storage battery is often well above 60 volts, so isolation is required. Corresponding on-board electrical systems or charging circuits thus have an isolation for the isolation of the on-board electrical system potentials with respect to a protective conductor potential or with respect to a chassis potential of the on-board electrical system. Especially during charging, when an external AC voltage source with a corresponding high rated voltage is connected to the vehicle, it must be ensured that there is no harmful contact voltage potential on the chassis or on components of the on-board electrical system. It should be ensured that the isolation is functional.

### SUMMARY

The disclosure provides a method for reliably detecting isolation faults. One aspect of the disclosure provides a method to operate a controlled rectifier according to an actuation signal, which is oriented, for example, to target operating parameters of the vehicle charging circuit (output voltage, output power, output current, etc.). A check is carried out in a DC voltage section or on a DC voltage side of the vehicle charging circuit or in an on-board electrical system connected thereto to determine whether an AC voltage component similar to the actuation signal arises there. If this is the case or if the signal strength of this AC voltage component (which is similar to or is part of the actuation signal) exceeds a threshold value, then an isolation fault is assumed.

Implementations of the disclosure may include one or more of the following optional features. In some implementations, in the case of an isolation fault, the AC voltage resulting from the operation of the rectifier is transmitted significantly more strongly or in a significantly less attenuated manner than in the case of a functioning isolation, and so an isolation fault can be inferred based on the detection of AC voltage components on the DC voltage side. For example, it is possible to investigate whether a voltage between a chassis potential or protective conductor potential and a DC voltage potential contains the AC voltage component or the actuation signal at a signal strength that exceeds a threshold value. As an alternative, the voltage between the two DC voltage potentials (on the DC voltage side) can be taken into account to ascertain whether there is an AC voltage signal similar to the actuation signal or the relevant AC voltage components with a signal strength that exceeds a threshold value. The actuation signal corresponds here to the pulse signal (PMW) using which the controlled rectifier is operated. The AC voltage component which partially or fully corresponds to the actuation signal is similar to the actuation signal. In other words, the AC voltage component partially or fully corresponds to the switching signal of the controlled rectifier. Since the switching signal, that is to say the switching pulses, in the power path correspond to the actuation signal (and vice versa), the AC voltage component to be examined partially or fully corresponds to both the actuation signal and the switching signal of the power path of the rectifier.

A method for detecting an isolation fault in a vehicle charging circuit therefore provides the clocked operation of the controlled rectifier according to an actuation signal. The vehicle charging circuit includes a DC voltage side and an AC voltage side. The DC voltage side is connected to the AC voltage side via a controlled rectifier of the vehicle charging circuit. The DC voltage side or at least one section thereof is isolated from a protective conductor potential. For example, at least one section of the DC voltage side is isolated from the protective conductor potential or the chassis potential. A further section of the DC voltage side which is not isolated from the protective conductor potential may be provided.

A device which transmits DC voltage or direct current between the two sections and still provides electrical isolation may be provided on the DC voltage side. The isolation fault to be detected is present between a DC voltage potential on the DC voltage side, such as a section of the DC voltage side which is electrically isolated, and the protective conductor potential or the chassis potential. The isolation fault may be present in the charging circuit or in a circuit or component connected thereto (an on-board electrical system, an on-board electrical system section, a storage battery, etc.), where the isolation fault affects the charging circuit in equal measure. Therefore, isolation faults caused by the charging circuit and isolation faults caused by a connected circuit or component are likewise referred to as isolation faults in the charging circuit, since causes outside the charging circuit also affect the charging circuit. Therefore, “isolation faults in the charging circuit” refers to all isolation faults that affect the charging circuit.

A protective conductor potential can be provided within the vehicle charging circuit and is connected to the chassis potential (within the charging circuit). In some examples, an AC voltage terminal is provided, to which an external AC voltage source or AC power source can be connected, the AC voltage terminal having a protective conductor potential. This potential of the terminal may be connected to the chassis potential of the vehicle in which the vehicle charging circuit is located. As mentioned, the two terms “protective conductor potential” and “chassis potential” can be interchanged due to the equipotentiality.

The controlled rectifier has switching elements which are controlled by a switching signal outside of the switch. In other words, the switches have an actuation input which can be used to set whether or not the switch is closed in the power path. The controlled rectifier may be a semiconductor rectifier and has electronic semiconductor switches, that is to say semiconductor switches having an actuation input such as a base, a gate or the like. The actuation inputs of the semiconductor switches are actuated by an actuation signal, for example from a control device. Rectifying units, such as rectifier circuits with controllable switches such as (single-phase or multi-phase) full-wave rectifiers or power factor correction filters which, in addition to a rectifier circuit, also have working inductors, are generally referred to as rectifiers. The charging circuit may be an AC charging circuit set up for converting an AC charging voltage into a DC voltage (on the DC voltage side).

The controlled rectifier is set up to rectify an AC voltage present on the AC voltage side in a controlled manner and to output the rectified voltage on the DC voltage side. The DC voltage side may be referred to as the secondary side, while the AC voltage side is the primary side. The voltage can be measured on the DC voltage side (secondary side) as described and a fault signal can be output if the voltage contains an AC voltage component which partially or fully corresponds to the actuation signal (primary side). In this case, power is transmitted from the primary side to the secondary side (forward operation), the signal is generated on the primary side and captured on the secondary side. An electrically isolating DC/DC voltage converter may be connected to the DC voltage side of the rectifier.

The terms secondary and primary refer to the direction of power flow in forward mode and are used in this manner in reverse mode (in a bidirectional charging circuit). In reverse mode, power is transmitted from the secondary side to the primary side. In forward mode, this is reversed.

The vehicle charging circuit may be of bidirectional design. The method may also be used in a circuit in which power is transmitted from the secondary side to the primary side of the rectifier. The method may also be used in a reverse-operated, bidirectional charging circuit (reverse mode). On the secondary side (or in the DC/DC voltage converter connected to the secondary side of the rectifier), the clocked operation is carried out according to the actuation signal, such as by way of a circuit which rectifies in forward mode and operates as a chopper in reverse mode (or switches in a clocked manner). This circuit may be part of the secondary side of the rectifier or the DC/DC voltage converter. An AC voltage generated by the rectifier in reverse mode arises on the primary side (in relation to the rectifier). In reverse mode, the rectifier generates an alternating current on the AC voltage side.

There is a voltage on the AC voltage side. An isolation fault signal is output when the voltage contains an AC voltage component which partially or fully corresponds to the actuation signal (the secondary side of the rectifier or the optional DC/DC voltage converter). For example, the fault signal is output only if it has a signal strength which exceeds a predetermined threshold value.

In other words, on the side on which clocked operation according to an actuation signal is carried out in forward mode, the voltage can be ascertained in reverse mode and it is possible to check for the presence of the AC voltage components (in order to output an isolation fault signal if the signal strength exceeds the threshold). This side may be the AC voltage side of the vehicle charging circuit (for forward mode) and, in reverse mode, may also be the rectifier, but also a DC-DC voltage converter, which is connected to the direct current side of the rectifier.

On the side where the voltage is present in forward mode and is being investigated with respect to the AC voltage component (to output an isolation fault signal if necessary), clocked operation is carried out according to an actuation signal in reverse mode. This side is the DC voltage side of the vehicle charging circuit, for example the DC voltage side of the rectifier or DC/DC voltage converter (such as the side thereof remote from the rectifier). This relates to forward mode. In reverse mode, this relates to the AC voltage side of the rectifier, or else to the DC voltage side thereof or to the side of the DC/DC voltage converter connected downstream of the rectifier, which is closer to the rectifier.

In some implementations, the vehicle charging circuit has a DC voltage side which is isolated from a protective conductor potential, an AC voltage side and a controlled rectifier via which the DC voltage side is connected to the AC voltage side. The vehicle charging circuit is bidirectional. In reverse operation mode, also known as output mode, feedback mode, or supply mode, the rectifier is operated to convert a power or DC-side voltage into AC voltage. In this mode, the rectifier operates as a frequency converter. The rectifier is operated in a clocked manner according to an actuation signal to generate an AC voltage on the AC voltage side. The actuation signal is set up, in addition to the frequency conversion, to generate a potential difference with respect to the protective conductor potential, which corresponds to a test alternating signal. A voltage present between DC voltage potentials of the DC voltage side or between a DC voltage potential of the DC voltage side and the protective conductor potential is measured. For example, the voltage is measured on one side of an electrically isolating DC/DC voltage converter or another electrically isolating unit, which converter or unit has another opposite side which is connected to the controlled rectifier. An isolation fault signal is output (and/or a disconnection is performed and/or charging circuit operation is interrupted) if the voltage contains an AC voltage component which partially or fully corresponds to the test alternating signal and has a signal strength which exceeds a predetermined threshold value.

This specifically generates on the primary side a test signal which corresponds to an AC voltage with respect to the protective potential, and a check is carried out to determine whether the (alternating) potential offset representing this test signal is present on the secondary side with a minimum signal strength. This enables the method to be applied even in reverse mode. A suitably equipped vehicle charging circuit has a signal generator set up to generate the test signal and to actuate the rectifier accordingly (in frequency converter mode). A corresponding vehicle charging circuit furthermore has a voltmeter which measures the potential offset on the secondary side (for example as voltage, power or current) with respect to the protective conductor potential, and an evaluation unit which compares this quantity with a threshold value and is set up to output an isolation fault signal (only) when the threshold value is exceeded.

The clocked operation of the controlled rectifier according to the actuation signal makes provision for the switches of the rectifier to be opened or closed according to the actuation signal. The actuation signal is clocked to achieve a desired rectification or a desired output current or a desired output voltage. For example, the rectifier is clocked to correct a power factor or to generate a (compensating) reactive power and in particular to reduce harmonics. Therefore, the actuation signal may also be designed according to a desired reactive power signal or equalization signal.

In order to ascertain whether an AC voltage component sufficiently similar to the actuation signal passes from the AC voltage side to the DC voltage side with a signal strength which exceeds a threshold value, a voltage on the DC voltage side is measured. This voltage may be approximately between DC voltage potentials on the DC voltage side (either in an electrically isolated area of the DC voltage side or in an electrically non-isolated area of the DC voltage side). As an alternative, the voltage may be present between a DC voltage potential of the DC voltage side and the protective conductor potential, such as between the protective conductor potential and a DC voltage potential of an electrically isolated or an electrically non-isolated section of the DC voltage side. The DC voltage potentials on the DC voltage side are power potentials, that is to say carry the power output by the rectifier (as power signal) as DC voltage.

An isolation fault signal is output when the voltage (on the DC voltage side as illustrated) contains an AC voltage component similar to the actuation signal or the alternating signal components thereof. The AC voltage component is similar to the actuation signal with a degree of similarity which exceeds a predetermined threshold value. For example, a correlation or a spectral comparison with one or more frequency bands or individual frequencies may be used as a degree of similarity. The similarity of the AC voltage component and the actuation signal does not relate to the amplitude, but only to the profile or to alternating signal parameters (frequency, spectrum, aperiodic AC voltage components, etc.). An isolation fault signal is output when the AC voltage component in the voltage corresponds to the actuation signal in terms of its profile or in terms of at least one frequency. In this case, the AC voltage component can partially correspond to the actuation signal if the AC voltage component has one or more predetermined AC voltage components of the actuation signal. The AC voltage component can also fully correspond to the actuation signal, where the profile of the AC voltage component corresponds to the profile of the actuation signal. In the case of multiple individual switches of the rectifier, the actuation signal corresponds to the totality of all individual switching signals. The actuation signal may be shown for comparison with the AC voltage component by way of at least one frequency component of the actuation signal, by way of the repetition frequency of switching edges, by way of the duty ratio of edges or states in the actuation signal or by way of switching times of the switches of the rectifier or by way of other characteristics of the operation of a controlled rectifier. It is possible to check whether the AC voltage component has a minimum degree of similarity with the actuation signal, with or without taking into account the absolute switching times in the actuation signal. Furthermore, when detecting the similarity or whether the AC voltage component is partially or fully included in the switching signal, it is also possible to consider only one switching frequency or only a plurality of frequencies of the actuation signal. This frequency or these frequencies correspond(s) to the AC voltage component. If one or more frequencies are searched for as an AC voltage component, then a check is carried out to determine whether this AC voltage component is included in the actuation signal. This corresponds to the check to determine whether the AC voltage component (with one or with a plurality of frequencies partially included in the actuation signal, which also contains further frequency components) or partially corresponds to this actuation signal.

Furthermore, the isolation fault signal is output when this AC voltage component which partially or fully corresponds to the actuation signal (for example, with respect to its profile or with respect to at least one frequency component) and, when it is specified that the AC voltage component is included in the actuation signal with a signal strength which exceeds a predetermined threshold value. This prevents false positive isolation fault signals that can occur with real, functioning isolation, since a resistive, inductive or capacitive, marginal coupling across the isolation cannot be excluded. Furthermore, the isolation fault signal can only be output if, as a further condition, the signal strength is fulfilled for at least one period of time continuously in the AC voltage component with the signal strength above the predetermined threshold value. In other words, the outputting of the isolation fault signal can be debounced, in particular according to a predetermined period of time over which the AC voltage component is present (continuously) in the voltage with the signal strength above the threshold value.

The voltage can be measured in a section of the DC voltage side which is not electrically isolated from the rectifier or from the AC power terminal, or in a section of the DC voltage side which is electrically isolated from the rectifier. The vehicle charging circuit may include an electrically isolating unit, such as a unit via which the DC voltage of the rectifier is transmitted into a section of the DC voltage side which is electrically isolated from the DC voltage converter. This electrically isolating unit may be provided as an electrically isolating DC/DC voltage converter. The voltage can thus be measured on one side of an electrically isolating unit (or a DC/DC voltage converter) which points away from the rectifier and is electrically isolated therefrom. This unit has another opposite side which is connected to the controlled rectifier. The voltage can thus be measured on the side of the electrically isolating unit which is remote from the rectifier (that is to say an electrically isolated section). The electrically isolating unit thus has a first side which is connected to the controlled rectifier and in particular is not electrically isolated from the rectifier or the AC voltage terminal, and has a second side which is electrically isolated from the AC voltage terminal or the rectifier.

As an alternative, the voltage can be measured on the side of the electrically isolating unit (such as a DC/DC voltage converter) which is electrically connected to the rectifier. In some examples, the voltage can be measured in a DC link which connects the rectifier to the electrically isolating unit (such as a DC/DC voltage converter). This results for a voltage present between the DC voltage potentials. When a voltage present between a DC voltage potential and the protective conductor potential is measured, it may be measured on the second side of the electrically isolating unit or in a section of the DC voltage side which is electrically isolated from the rectifier or the AC voltage terminal. As mentioned, given a voltage present between the DC voltage potential, the voltage is measured in an area which is not electrically isolated from the rectifier or from the AC voltage terminal.

In some implementations, the AC voltage component is an alternating signal which arises in usual, unmodified operation of the rectifier. In other words, the AC voltage component is obtained through the operation of the rectifier, that is to say through the rectifying function of the rectifier. In some examples, the AC voltage component may be an alternating signal determined by the function of the controlled rectifier to generate a (compensating) reactive power component or to reduce harmonics. The AC voltage component can therefore be determined according to the proper operation of the rectifier. In this case, it is only necessary to determine whether the signal strength of the AC voltage component resulting from the proper operation of the rectifier is above the threshold value. In this case, the actuation signal is generated through the proper operation of the rectifier. In some examples, the actuation signal is generated in accordance with closed-loop or open-loop control which is in turn executed according to a target operating parameter of the vehicle charging circuit. Parameters that are necessary for the intended operation of the rectifier, for example operating parameters such as the nominal voltage, the nominal power, the nominal power factor or the nominal reactive power or else the nominal harmonic upper limit, are regarded as target operating parameters. Parameters resulting from rectifying operation or from operation as a power factor correction filter for the rectifier are thus considered as target operating parameters. The target operating parameters relate to the operation of the vehicle charging circuit for transmitting a target power or for generating a target direct current or a target voltage on the DC voltage side of the vehicle charging circuit. As an alternative, or in combination therewith, the closed-loop or open-loop control is performed according to the target operating parameters of the rectifier which is in the form of a power factor correction filter. These target operating parameters relate to a target reactive power, a target harmonic upper limit, a target power factor or similar operating parameters which characterize the operation as a power factor correction (PFC) filter. If the rectifier is in the form of a power factor correction filter, it may have operating impedances such as operating inductors connected to the switches. In some examples, the switches of the rectifier are connected to the AC voltage terminal via operating inductors in order to correct a power factor (by generating reactive power) in a targeted manner. If the AC voltage component used is an alternating signal which occurs in any case during normal operation of the rectifier, that is to say which characterizes the operation of the rectifier as a rectifier itself or as a power factor correction filter, then this signal can be used for isolation fault detection. In other words, the AC voltage component which characterizes the rectifying function or the power factor correction filter function in the rectifier can then be used to check whether it arises in the voltage with a signal strength above the predetermined threshold value. This corresponds to the consideration of the already occurring AC voltage component as a test signal for checking the isolation.

As an alternative or else in combination, the actuation signal can be modulated using a test signal. The test signal can then correspond to the AC voltage signal. The AC voltage signal can also correspond not only to the test signal, but also to the alternating signal resulting from the operation of the rectifier as a rectifier itself or as a power factor correction filter. In this case, the switching signals for the switches of the rectifier can already be modulated using the test signal, or the test signal is indexed to the DC voltage side of the rectifier. The rectifier can thus be operated not only according to the operating parameters, but also according to the test signal. The actuation signal can be modulated using the test signal in such a way that a modulated voltage between the DC voltage potential is obtained by the modulation by the test signal or that a modulation of the voltage between the protective conductor potential and one of the DC voltage potentials results by the test signal. The actuation signal is modulated using the test signal in such a way that a modulated output voltage results (for example, in a non-electrically isolated section of the DC voltage side), then the test signal may be a signal with a frequency significantly below the switching frequency of the rectifier (which results from operation as a rectifier or as a power factor correction filter). For example, a modulation with a frequency of less than 10 Hz can be provided by the test signal, where the DC voltage signal which is output by the rectifier is then also modulated with this voltage. Since the frequency differs significantly from the expected ripple frequency on the DC voltage side of the rectifier, the AC voltage component in question can be easily detected. If the actuation signal is modulated using the test signal in such a way that a voltage between the protective conductor potential and one of the DC voltage potentials is obtained, which is modulated according to the test signal, then a test signal can be used at a frequency which is significantly above the switching frequency of the switching elements of the rectifier, where the switching frequency is due to the function as a rectifier or power factor correction filter. In some examples, the frequency of the test signal is below 1 kHz and such as below a frequency of an isolation monitor test signal which is actively fed in for isolation monitoring. This is used to separate the present method from the operation of active isolation monitors. For example, the test signal is generated by a test signal generator.

The test signal may be an alternating signal with a predetermined spectrum, for example with a spectrum which essentially has only one frequency component, or may correspond to a square-wave signal which has a specific edge frequency (reciprocal value of the pulse duration). The test signal may be provided as a noise signal, as a pseudo-noise signal. This enables interference-free recognition or detection in the voltage measured on the DC voltage side. The test signal may also have a signal component of a frequency that does not constitute more than a minor component of the unmodulated actuation signal. In other words, the alternating signal in the frequency range dominated by the unmodulated actuation signal may have a signal component which is below a threshold value. In other words, the spectrum of the test signal preferably significantly differs from the spectrum of the unmodulated (that is to say from closed-loop or open-loop control) resulting actuation signal. In some examples, most of the power of the test signal is in a spectral section in which the power of the actuation signal is below a threshold value or at least 20, 30 or 40 decibels below the power of the frequency range with the highest power.

The actuation signal may be modulated using a test frequency, that is to say at a frequency of the test signal which (at a predefined spacing) is below or above the frequency resulting from the operation of the rectifier in the rectifying function or in the function as a power factor correction filter. In some examples, the test frequency (frequency of the test signal) is below or above the frequency assigned to the largest power component within the AC component of the voltage when the rectifier is operated in a clocked mode according to the target operating parameter. The frequency of the test signal therefore differs from the frequency corresponding to the largest AC power component in the DC voltage (of the electrically non-isolated range) or the electrically isolated range on the DC voltage side. The test frequency is therefore a frequency which differs sufficiently from the frequencies occurring during normal operation of the rectifier (as a rectifying unit or as a power factor correction filter).

The AC voltage signal has a frequency of substantially 50 Hz, 60 Hz, 150 Hz or 180 Hz, with the frequency not deviating more than 2%, 5% or 10% from 50 Hz, 60 Hz, 150 Hz or 180 Hz. This is especially the case if the voltage between a protective conductor potential and a DC voltage potential matches. As an alternative, the actuation signal is modulated using a test signal whose frequency is less than 20 Hz, 10 Hz, 5 Hz or 2 Hz. The frequency does not deviate more than 2%, 5% or 10% from 20 Hz, 10 Hz, 5 Hz or 2 Hz. Another aspect is that the frequency of the AC voltage signal or the test signal is below 1 kHz. If an (active) isolation monitor is provided in the on-board electrical system with a test signal of 1 kHz or higher, this ensures that the method is not adversely affected by the active isolation monitor, and vice versa.

The voltage may be measured on a side of an electrically isolating unit (for example a DC/DC voltage converter) which is connected to the controlled rectifier. This may correspond to an electrically non-isolated section of the DC voltage side of the charging circuit. The side of the electrically isolating unit connected to the controlled rectifier is electrically conductively connected to the rectifier. If the controlled rectifier is also not electrically isolating, then the voltage is detected in an area of the DC voltage side that is not electrically isolated (from the protective conductor potential). In some implementations, the voltage is measured at this point if it corresponds to the voltage between two DC voltage potentials. In this case, the actuation signal is modulated using a test signal, the frequency of which is below the network frequency of the AC voltage terminal or the AC voltage side of the rectifier. For example, at a voltage detected at this point, the actuation signal may be modulated using a test signal whose frequency is not more than 10 Hz, 5 Hz, 2 Hz or 1 Hz. The frequency does not deviate more than 2%, 5% or 10% from 5 Hz, 2 Hz or 1 Hz, 10 Hz. If an isolation fault is identified according to the method, then provision may be made for a vehicle-based connection to be interrupted, or for an interruption signal which causes an external charging source to interrupt the connection to the vehicle-based charging circuit to be output. A method for operating the vehicle charging circuit described here therefore makes provision for the method for detecting an isolation fault mentioned here to be carried out, and for a vehicle-based connection to be interrupted when an isolation fault is detected and/or an interruption signal is output to a source outside the vehicle or to a controller thereof. In addition, an interruption signal can be output to a higher-level controller (based in the vehicle side or outside the vehicle, for example, in the charging source outside the vehicle) to cause an interruption (by indirect actuation).

Furthermore, a vehicle charging circuit is described, such as a vehicle charging circuit as is described based on the method. The vehicle charging circuit has a DC voltage side which is isolated from a protective conductor potential. In some implementations, the vehicle charging circuit has a section on a DC voltage side which is isolated from a protective conductor potential. The vehicle charging circuit may also have a section of the DC voltage side which is not electrically isolated from the protective conductor potential. Isolated in this case denotes the state in which the units in question are electrically isolated from one another.

The vehicle charging circuit also has an AC voltage side and a controlled rectifier. The DC voltage side is connected to the AC voltage side via the rectifier. As is also mentioned in the method, the AC voltage side may have an AC voltage terminal. This AC voltage terminal may correspond to the AC voltage terminal described here. An open-loop control device which is connected to the rectifier in an actuating manner is provided. The open-loop control device is preferably part of the vehicle charging circuit. The open-loop control device is set up to operate the rectifier in a clocked manner according to an actuation signal. In some examples, the open-loop control device is set up to output to the rectifier an actuation signal which implements open-loop or closed-loop control (as described here). The open-loop control device may be furthermore set up to output to the rectifier an actuation signal of this kind which enables the rectifier to perform the function of a controlled rectifier or to perform the function of a power factor correction filter. As mentioned above, both functions are linked to specific operating parameters which are available as target values (or which are used as default for the open-loop or closed-loop control).

An isolation fault determination unit of the vehicle charging circuit is set up to measure a voltage. This voltage is present between the DC voltage potentials on the DC voltage side (such as, in an electrically non-isolated section or also in an electrically isolated section). The voltage may also be present between a DC voltage potential of the DC voltage side and the protective conductor potential (of the AC voltage side), for example, in an electrically isolated section of the DC voltage side or else in an electrically non-isolated section of the DC voltage side. Electrically isolated is used here to denote potentials that are electrically isolated from the rectifier or from the protective conductor potential or from the AC voltage side or the AC voltage terminal. Electrically isolated is used to denote a component that is electrically isolated from the AC voltage side, the rectifier, the AC voltage terminal and/or the rectifier.

The isolation fault determination unit has a measuring unit that is set up to receive the voltage. The isolation fault determination unit and the measuring unit thus has an at least signal-transmitting connection which carries up to the potentials mentioned. The measuring unit is set up to receive the voltage. In some examples, the measuring unit is set up to receive a signal that corresponds to the voltage, and reproduces the profile. The measuring unit is not necessarily designed to receive the voltage at the amplitude at which it is applied to the potentials mentioned. This also applies to the isolation fault determination unit. A voltage divider or a digital-to-analog converter may be connected upstream of the isolation fault determination unit or the input thereof may be provided.

The measuring unit is designed to measure a signal strength of the AC voltage component present in the voltage. The AC voltage component corresponds to the AC voltage component mentioned in the method. This also applies to the voltage. The AC voltage component partially or fully corresponds to the actuation signal, as described above based on the method.

The isolation fault determination unit further includes a comparator. The comparator is set up to compare the signal strength with a predetermined threshold value. The comparator is also set up to output an isolation fault signal if the signal strength is greater than the threshold value. The comparator is also set up not to output an isolation fault signal if the signal strength is not greater than the threshold value. The output of no isolation fault signal is equivalent to the output of a signal indicating that there is no isolation fault.

Finally, an isolation fault determination unit set up to perform the method may be provided. Such an isolation fault determination unit is designed like the isolation fault determination unit described above. Such an isolation fault determination unit may be formed outside the vehicle charging circuit or may be formed as part of the vehicle charging circuit. The isolation fault determination unit has an input that can be connected to the respective potentials. The isolation fault determination unit may also have an input at which the actuation signal or a signal characterizing the actuation signal can be input. In this way, it is possible for the isolation fault determination unit to determine whether or not the actuation signal is present in the voltage with a signal strength above the threshold value. In the former case, the isolation fault determination unit would output an isolation fault or a corresponding signal and, in the latter case, the isolation fault determination unit would not report an isolation fault or output a corresponding isolation fault signal.

The options described here are used to identify an isolation fault in a vehicle charging circuit. If the isolation fault exists outside the vehicle charging circuit, for example in a connected on-board electrical system, and if the isolation fault is present in the connected on-board electrical system, the isolation fault is also present in the vehicle charging circuit due to this connection. The identification of an isolation fault in a vehicle charging circuit is thus equivalent to the identification of an isolation fault which affects the vehicle charging circuit and which is not necessarily caused by the vehicle charging circuit. Instead, the cause of the isolation fault may also be present in a connected circuit (on-board electrical system) or connected component, such that the isolation fault also affects the vehicle charging circuit and thus also constitutes an isolation fault in the vehicle charging circuit.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 illustrates and exemplary a circuit.

Like reference symbols in the various drawings indicate like elements.

### DETAILED DESCRIPTION

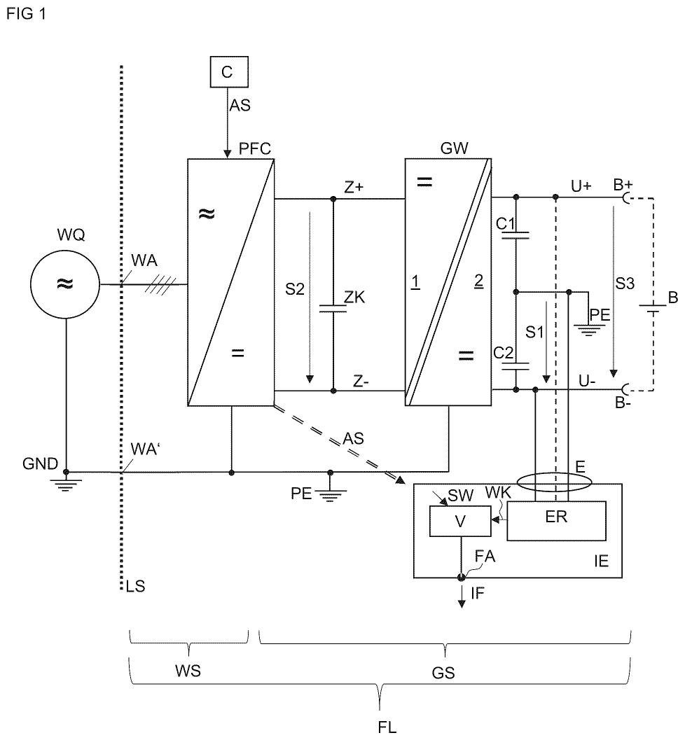

FIG. 1 shows a vehicle charging circuit FL with an AC voltage side, which includes an alternating voltage terminal WA, WA′. The AC voltage terminal includes a protective earth connection WA′ and an (exemplary) four-part/four-wire AC terminal WA, which may include three phase terminals and a neutral conductor terminal. The illustrated vehicle charging circuit FL further includes a rectifier PFC which provides an interface between a DC voltage side GS and an AC voltage side WS of the vehicle charging circuit FL. As shown, an electrically isolating DC/DC voltage converter GW (as well as an example of an electrically isolating unit) is connected by way of a first side 1 to the DC voltage side of the rectifier PFC. The DC/DC voltage converter GW has a second side 2 which is electrically isolated from the first side 1. The second side 2 is connected to an on-board electrical system terminal which has the contacts B+ and B−, that is to say two DC voltage potential contacts with different potentials. A component (storage battery) external to the charging circuit or an on-board electrical system external to the charging circuit can be connected to the second side. Isolation faults affect the charging circuit in this case and are therefore detected as described herein.

An AC voltage source WQ outside of the vehicle charging circuit is connected to the vehicle charging circuit FL, to the terminals WA and WA′. The rectifier PFC is a controlled rectifier which converts the power signal of the AC voltage terminal WA (AC) into a DC voltage with open-loop control. This DC voltage exists between the potentials Z+ and Z−, with these potentials being the potentials of a DC link. The DC link connects the rectifier PFC to the DC/DC voltage converter GW and has a DC link capacitor ZK which is used to smooth or support the voltage between Z+ and Z−, that is to say a DC voltage. The rectifier PFC is controlled by an actuation signal AS generated by an open-loop control device C. In some examples, when the rectifier PFC is in the form of a power factor correction filter, this generates an alternating signal which is present as a ripple voltage in the voltage between Z+ and Z− in the DC link. The rectifier downstream of the DC link or the rectifier PFC is electrically isolated so that, in the case of fault-free isolation (of the DC-DC voltage converter GW or other components connected to the charging circuit), essentially two of the DC-DC voltage converters GW do not arise on the second side. The isolation refers to the isolation between the DC voltage potentials U−/U+ on the second side of the DC/DC voltage converter, that is to say in an electrically isolated section of the DC voltage side GS with respect to the protective conductor potential PE or GND. If the isolation (between the DC voltage potentials of an electrically isolated section of the DC voltage side and the protective conductor potential PE) is defective, then the alternating signal arising when the rectifier PFC is activated is transferred to a voltage S1 between the protective conductor potential PE and one of the DC voltage potentials U− or U+. A corresponding voltage S1 is illustrated between the potential PE and the potential U−, in which there is an AC voltage component which originates from the actuation of the rectifier GR.

The signal strength of this AC voltage component is used to detect whether or not there is an isolation fault. The AC voltage component is transferred to an electrically isolated section of the DC voltage side GS only if the isolation between the protective conductor potential PE and a DC voltage potential U+ or U− of an electrically isolated section of the DC voltage side GS is defective or has too low an isolation resistance.

The entire alternating signal can be checked as an AC voltage component on the DC voltage side GS for isolation fault determination, or only a part thereof can be checked, only an AC voltage component, which makes up a part or only a spectrum of the alternating signal, which is derived entirely from the control of the rectifier PFC.

An isolation fault determination unit IE illustrated by way of example has a signal input E which is connected to the potentials PE and U− by way of example. As an alternative, the input can also be connected to the potentials PE and U+ or to the potentials U− and U+. A connection to the potentials Z+ and Z− is also conceivable. The voltages S1, S3 or S2 between these potentials are present at the input E, either as these voltages themselves or as a signal that reflects these voltages. A measuring unit ER is connected downstream of the input E of the isolation fault determination unit IE and measures an AC voltage component from this voltage (S1, S2 or S3) as illustrated above. A comparator V connected downstream of the determination unit ER determines whether or not the signal strength of the AC voltage component WK is greater than a threshold value SW. If the threshold value is reached or exceeded, an isolation fault signal IF is output at a fault output FA of the isolation determination unit IE. If the threshold value is not exceeded, no isolation fault signal IF is output.

Since the AC voltage component WK partially or fully corresponds to the actuation signal AS of the rectifier PFC, the characteristics of the AC voltage component WK to be detected are known to the determination unit ER. This is symbolically represented by the dashed double arrow which is used to indicate that the actuation signal AS generates alternating signals which can be detected by the isolation fault determination unit IE (using component ER) if an isolation fault is present. The determination unit ER can thus be set to the characteristics of the actuation signal AS. As an alternative, the determination unit ER can have an input at which the actuation signal, an AC voltage component (which may at least be part of the actuation signal) or a signal can be input that reproduces these signals. In this way, the determination unit ER can match the signal S1 (S2 or S3) with the AC voltage component WK to determine how high the signal strength of the AC voltage component WK is. The fact that the AC voltage signal WK is passed from the determination unit ER to the comparator is illustrated. Instead of this, the signal strength of the AC voltage component WK can also be passed from the determination unit to the comparator V. In the first case, the comparator V is able to generate the signal strength of the AC voltage component from the AC voltage component WK, which originates from the determination unit ER, in order to compare it with the threshold value SW.

The voltage containing the AC voltage component WK in the event of an isolation fault may be the voltage S1 between a protective conductor potential PE and a potential U− (or U+) of an electrically isolated section of the DC voltage side GS. In addition, this voltage may also correspond to the DC link voltage S2, that is to say the voltage between DC voltage potentials (power-DC potentials) in an electrically non-isolated section of the DC voltage side GS. Finally, the voltage S3 may be used as the voltage which is checked for the AC voltage component, where the voltage S3 between the potentials U+ and U− is present in an electrically isolated section of the DC voltage side GS.

The actuation signal AS may depend purely on the desired function of the rectifier (controlled rectification or function as power factor correction filter). In this case, the actuation signal AS is generated exclusively according to the associated operating parameters, these operating parameters being, for example, a desired output power of the rectifier, output current of the rectifier, output voltage of the rectifier, reactive power of the rectifier, target power factor and/or frequency of the generated reactive power. When functioning as a power factor correction filter, the rectifier can be operated as an active power factor correction filter to generate a desired reactive power which at least partially compensates for another reactive power which is to be compensated. This reduces undesirable effects on an external AC voltage source WQ. In other words, the actuation signal for the rectifier GR which is customary for operation can be used as the actuation signal, without further modification of this signal with regard to other functions. As an AC voltage component, this actuation signal which is typical of operation or signal components thereof can then be used to check whether or not components of the actuation signal with a certain signal strength are transmitted to the DC voltage side due to faulty isolation. This indicates the fault state of the isolation.

As an alternative, the open-loop control C for additional modulation may be set up to thus specifically generate a test signal which is not used for the usual operation of the rectifier (controlled rectification or power factor correction filters), but which serves for the isolation fault identification shown. In this case, the actuation signal resulting from normal operation can be additionally modulated to generate a test signal present between one of the DC voltage potentials Z+, Z−, U+, U− on the one hand and the protective conductor potential PE on the other. As an alternative, the (re-modulated) actuation signal can be modulated in such a way as to obtain a test signal resulting between DC voltage potentials of the DC voltage side, for example a test signal voltage as AC voltage in the voltage S2 in the DC link or S3 in an electrically isolated section of the DC voltage side. The DC link is not electrically isolated and forms an electrically non-isolated section of the DC voltage side GS. If a test signal is to be generated by modulation between the protective conductor potential and another voltage, the test signal used is preferably an AC voltage with a frequency of less than 1 kHz, preferably with a frequency different from the frequencies generated through normal operation of the rectifier PFC. If the modulation generates a test signal which relates to a voltage between two DC voltage potentials (for example between Z− and Z+ or between U− and U+, that is to say voltages S2 or S3), then an AC voltage having a frequency below the basic frequency of the actuation of the rectifier PFC is preferably used as a test signal. For example, a corresponding frequency may be approximately 10, 5, 2, or 1 Hz.

Finally, a further on-board electrical system, for example a battery B designed, for example, as a high-performance traction storage battery, can be connected to the terminals B+ and B− of the electrically isolated section of the DC voltage side GS. This connecting on-board electrical system is not part of the charging circuit.

FIG. 1 shows a protective conductor potential on the side of the AC voltage source, which is shown as ground potential GND. A protective conductor potential designed as a chassis potential is also provided in the vehicle charging circuit. This example relates to potentials of different origin, but the same electrical potential, since the potentials are connected to one another. In order to illustrate the different origin of the two potentials, the reference GND is used for the protective conductor potential of the AC voltage source WQ.

The electrically isolated section of the DC voltage side GS illustrated further includes a capacitive voltage divider having the capacitors C1 and C2. The potential PE is applied to the linking point of this capacitive voltage divider, that is to say a chassis potential. The voltage containing the AC voltage component in the event of an isolation fault may also be the voltage S1 which lies between the linking point of the capacitive voltage divider C1, C2 and the potential U−, which is a DC voltage potential of an electrically isolated section of the DC voltage side GS. The electrically non-isolated section of the DC voltage side GS extends from the DC voltage side of the rectifier PFC to the first side 1 of the rectifier GW. An electrically isolated section of the DC voltage side GS extends from the second side 2 to the terminals B+, B− of the charging circuit.

The rectifier GW is set up to transmit electrically isolating power from the first side 1 to the second side 2. The first side 1 is connected to the DC voltage side of the rectifier BFC, while the side 2 remote therefrom is connected to the terminals B+, B− or has the potentials U− and U+.

A number of implementations have been described. Nevertheless, it will be understood that various modifications may be made without departing from the spirit and scope of the disclosure. Accordingly, other implementations are within the scope of the following claims.

What is claimed is:

1. A method for detecting an isolation fault in a vehicle charging circuit which having a DC voltage side which is isolated from a protective conductor potential, an AC voltage side, and controlled rectifier via which the DC voltage side is connected to the AC voltage side, the method comprising:
clocking operation of the controlled rectifier according to an actuation signal;
measuring a voltage present between DC voltage potentials of the DC voltage side or between a DC voltage potential of the DC voltage side and the protective conductor potential; and
outputting an isolation fault signal when the voltage contains an AC voltage component which partially or fully corresponds to the actuation signal and which has a signal strength above a predetermined threshold value.

2. The method of claim 1, wherein the voltage is measured on one side of an electrically isolating DC/DC voltage converter or another electrically isolating unit, which converter or unit has another opposite side which is connected to the controlled rectifier.

3. The method of claim 1, wherein the actuation signal is generated in accordance with closed-loop or open-loop control which is executed according to at least one target operating parameter of the vehicle charging circuit or the actuation signal is generated in accordance with closed-loop or open-loop control which is executed according to at least one target operating parameter of the rectifier in a form of a power factor correction filter.

4. The method of claim 3, wherein the actuation signal is modulated using a test signal which corresponds to the AC voltage component.

5. The method of claim 4, wherein the test signal is generated as a noise signal, as a pseudo-noise signal, or as an alternating signal having a signal component of a frequency which is not more than a minor component of the unmodulated actuation signal.

6. The method of claim 3, wherein the actuation signal is modulated using a test frequency below or above the frequency assigned to the largest power component in the alternating component of the voltage in the clocked operation of the rectifier according to the target operating parameter.

7. The method of claim 3, wherein the AC voltage component has a frequency of 50 Hz, 60 Hz, 150 Hz or 180 Hz with a maximum deviation of not more than 2%, 5% or 10%, or the actuation signal is modulated using a test signal whose frequency is less than 20 Hz or 5 Hz or 10 Hz with a maximum deviation of not more than 2%, 5% or 10%, and/or the frequency of the AC voltage component is less than 1 kHz.

8. The method of claim 1, wherein the voltage is measured on one side of an electrically isolating DC/DC voltage converter or another electrically isolating unit connected to the controlled rectifier.

9. The method of claim 8, wherein the actuation signal is modulated using a test signal whose frequency is not more than 5 Hz.

10. The method of claim 9, wherein the frequency of the test signal is not more than 2 Hz or 1 Hz.

11. A method for operating a vehicle charging circuit, comprising:
execution of the method of claim 1, and
interrupting a vehicle-based connection when an isolation fault has been detected, or
outputting an interruption signal to a vehicle-external charging source or an open-loop control system thereof.

12. A vehicle charging circuit comprising:
a DC voltage side which is isolated from a protective conductor potential;
an AC voltage side and a controlled rectifier via which the DC voltage side is connected to the AC voltage side, wherein an open-loop control device is connected to the rectifier in an actuating manner and is set up to operate same in a clocked mode in accordance with an actuation signal;
an isolation fault determination unit designed to measure a voltage between DC voltage potentials of the DC voltage side or between a DC voltage potential of the DC voltage side and the protective conductor potential, the isolation fault determination unit includes:
a measuring unit set up and designed to receive the voltage, to measure a signal strength of the AC voltage component present in the voltage, which AC voltage component partially or fully corresponds to the actuation signal, and
a comparator set up to compare the signal strength with a predetermined threshold value and then output an isolation fault signal when the signal strength is greater than the threshold value.

13. A method for identifying an isolation fault in a bidirectional vehicle charging circuit which has a DC voltage side which is isolated from a protective conductor potential, has an AC voltage side and has a controlled rectifier via which the DC voltage side is connected to the AC voltage side, wherein, in an output mode, the method comprises:
clocking operation of the rectifier according to an actuation signal such that an AC voltage is generated on the AC voltage side, wherein the actuation signal is set up to generate, in addition to this conversion, a potential difference with respect to the protective conductor potential, which corresponds to a test alternating signal;
measuring a voltage present between DC voltage potentials of the DC voltage side or between a DC voltage potential of the DC voltage side and the protective conductor potential; and
outputting of an isolation fault signal when the voltage contains an AC voltage component which partially or fully corresponds to the test alternating signal and which has a signal strength above a predetermined threshold value.
